(19) United States
(12) Patent Application Publication
(10) Pub. No.: US 2010/0224914 A1
(43) Pub. Date: Sep. 9, 2010

(54) SEMICONDUCTOR DEVICE

(75) Inventors: Toshiyuki IWAMOTO, Kanagawa (JP); Gen TSUTSUI, Kanagawa (JP); Kiyotaka IMAI, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/715,712

(22) Filed: Mar. 2, 2010

(30) Foreign Application Priority Data
Mar. 5, 2009 (JP) 2009-52681

(51) Int. Cl. H01L 29/04

(52) U.S. Cl. 257/255; 257/E29.004

(57) ABSTRACT

Provided is a semiconductor device including: a first n-channel fin-type field effect transistor formed on a first crystal plane; and a second n-channel fin-type field effect transistor formed on the first crystal plane and having a gate length longer than that of the first n-channel fin-type field effect transistor. A side surface of a fin of the first n-channel fin-type field effect transistor and a side surface of a fin of the second n-channel fin-type field effect transistor are both formed on a second crystal plane having a carrier mobility lower than that of the first crystal plane. The width of the fin of the second n-channel fin-type field effect transistor is greater than the width of the fin of the first n-channel fin-type field effect transistor.

### CROSS-REFERENCE TO RELATED APPLICATIONS

This application is based upon, claims the benefit of priority of, and incorporates by reference the contents of Japanese Patent Application No. 2009-052681.

### BACKGROUND OF THE INVENTION

The present invention relates to semiconductor devices, and more particularly to a field effect transistor.

A fin-type field effect transistor is a sort of FET (Field Effect Transistor) and has a device structure which is most promising for 22-nm node and beyond. The fin-type field effect transistor is advantageous in that tolerance to short channel effect is higher, compared to conventional planar MOSFETs (Metal Oxide Semiconductor Field Effect Transistor), and random dopant fluctuation can be reduced. In this way, the fin-type field effect transistor is useful in constructing a transistor having a significantly small gate length; thus its development has been under way with the increased miniaturization of LSI (Large Scale Integration). As an example of fin-type field effect transistor, Japanese Patent Laid-Open No. 2005-86024 (its counterpart, U.S. Pat. No. 7,129,550 (B2)) has disclosed a semiconductor device and a manufacturing method thereof.

FIG. 1 is a top view illustrating the structure of the semiconductor device disclosed in Japanese Patent Laid-Open No. 2005-86024 (hereinafter referred to as Patent Document 1). This semiconductor device includes a semiconductor substrate (not illustrated), a semiconductor layer 115, a gate insulating layer (not illustrated), a gate electrode 114, a channel region (not illustrated), a source/drain extension region (not illustrated), and source and drain regions 111 and 112.

The semiconductor layer 115 is formed on the semiconductor substrate and has a shape of fin which is longer in the x-direction and shorter in the y-direction orthogonal to the x-direction. The gate insulating layer is formed on a side surface of the semiconductor layer 115 along the y-direction. The gate electrode 114 is arranged adjacent to the gate insulating layer. The channel region is formed at a position adjacent to the gate insulating layer in the semiconductor layer 115. The source/drain extension region is formed at a position adjacent to the channel region in the semiconductor layer 115 in the x-direction. The source and drain regions 111 and 112 are formed at a position adjacent to the source/drain extension region in the semiconductor layer 115 in the x-direction. The width of the semiconductor layer 115 in the y-direction in the channel region is smaller than the width of the semiconductor layer 115 in the y-direction in the source and drain regions 111 and 112.

International Publication WO 2005/038931 (its counterpart, U.S. Patent Application: US2007075372 (A1)) has disclosed a semiconductor device and a manufacturing process therefor. This semiconductor device includes a projection-shaped semiconductor region arranged on a substrate, a projection-shaped source/drain region formed in a manner having the semiconductor region therebetween, and a gate electrode arranged via an insulating film at least on a side surface of the semiconductor region. In the semiconductor device, at least the maximum width of the source/drain region is greater than the width of the semiconductor region; and the source/drain region has a slope having a width continuously increasing from the uppermost side to the substrate side; and a silicide film is formed on the surface of the slope.

With respect to such a fin-type field effect transistor, the inventor has first discovered the following problem.

In the semiconductor device using a fin-type field effect transistor such as one described in Patent Document 1, the fin-type field effect transistor is constructed to have a smaller width of fin. This is because, as the width of fin becomes smaller, tolerance to short channel effect increases, so that random dopant fluctuation is reduced accordingly. However, a decrease in the width of fin may result in a narrower channel region, thus reducing the drive current; consequently, current drive capacity may be reduced. For the semiconductor device using a fin-type field effect transistor, a technique of raising the current drive capacity is desired.

Meanwhile, it is known that electron mobility and hole mobility in the channel region of a semiconductor device vary from crystal plane to crystal plane. For example, a non-patent document titled “three-dimensional stress engineering in fin-type field effect transistors for mobility/on-current enhancement and gate current reduction” (M. Saitoh, et. al, Dig. Symp. VLSI Tech. 2008, IEEE, p. 18-19) has disclosed a relationship of electron mobility and hole mobility to Si crystal plane. FIGS. 8A and 8B are graphs illustrating a relationship between the drain current and the gate length of a transistor on Si (100) plane and Si (110) plane, which are disclosed in this non-patent document; the abscissa represents gate length (Lg (μm)) and the ordinate represents a ratio between drain current (Ids (110)) on Si (110) plane and drain current (Ids (100)) on Si (100) plane. FIG. 8A corresponds to nFET (electron carrier); and FIG. 8B corresponds to pFET (hole carrier).

As illustrated in FIG. 8A, in nFET, as gate length Lg becomes longer (in the right side of FIG. 8A), drain current Ids (110) on (110) plane decreases to approximately half of drain current Ids (100) on (100) plane. Here, drain current Ids is chiefly determined by carrier mobility, and FIG. 8A indicates that electron mobility of (110) plane decreases to approximately half of electron mobility of (100) plane. On the other hand, as illustrated in FIG. 8B, in pFET, as gate length Lg becomes longer (in the right side of FIG. 8B), drain current Ids (110) increases to approximately twice drain current Ids (100). That is, FIG. 8B indicates that hole mobility of (110) plane increases to approximately twice hole mobility of (100) plane.

When channel length is longer, current drive capacity is directly affected by carrier mobility. Thus, in nFET (FIG. 8A), when channel length is longer (that is, when gate length is longer), current drive capacity of (110) plane decreases, due to the above relationship with electron mobility, to approximately half of current drive capacity of (100) plane. On the other hand, in pFET (FIG. 8B), when channel length is longer (that is, when gate length is longer), current drive capacity of (110) plane increases, due to the above relationship with hole mobility, to approximately twice current drive capacity of (100) plane.

Accordingly, when a fin-type field effect transistor having a smaller fin width is used in nFET having a longer gate length, the following problem may occur.

That is, when a fin-type field effect transistor (nFET) is formed on (100) substrate and a fin is formed in a <110> direction, the channel plane of this fin-type field effect transistor is formed so that the side surface of the fin corresponds to (110) plane and the upper surface of the fin corresponds to (100) plane. Further, in the fin-type field effect transistor having a smaller fin width, the side surface region of the fin is wider than the upper surface region of the fin. Consequently, in the fin-type field effect transistor having a smaller fin width, (110) plane is dominant as the channel plane. However, in an ordinary MOSFET, the upper surface of (100) substrate, that is, (100) plane acts as the channel surface. Here, as described above (FIG. 8A), current drive capacity of (110) plane is approximately half of current drive capacity of (100) plane. When this fact is applied to the fin-type field effect transistor having a smaller fin width and the ordinary MOSFET, it is thought that the current drive capacity of the fin-type field effect transistor having a smaller fin width is approximately half of the current drive capacity of the ordinary MOSFET.

That is, in a region having a longer gate length, when a fin-type field effect transistor having a smaller fin width is used in nFET, current drive capacity decreases to approximately half of the current drive capacity of an ordinary MOSFET. In this way, in using a fin-type field effect transistor in LSI, when only the fin width is decreased, transistor capacity may lower, and thus its function cannot be fully achieved. Accordingly, a technique is desired which can improve transistor characteristics (for example, current drive capacity, tolerance to short channel effect, and random dopant fluctuation) irrespective of gate length.

### SUMMARY

A solution for addressing the problem will be described below using reference numbers and characters used in an embodiment for implementing the invention. These reference numbers and characters are parenthesized to clarify the corresponding relationship between the claims and the embodiment for implementing the invention. However, the reference numbers and characters should not be used for interpretation of the technical scope of the invention described in the claims.

A semiconductor device according to the present invention includes a first n-channel fin-type field effect transistor (1) formed on a first crystal plane ((100) by way of example) and a second n-channel fin-type field effect transistor (2) formed on the first crystal plane ((100) by way of example) and having a gate length (Lg) longer than that of the first n-channel fin-type field effect transistor (1). A side surface of a fin (15) of the first n-channel fin-type field effect transistor (1) and a side surface of a fin (25) of the second n-channel fin-type field effect transistor (2) are both formed on a second crystal plane ((110) by way of example) having a carrier mobility lower than that of the first crystal plane ((100) by way of example). The width (WfinB) of the fin (25) of the second n-channel fin-type field effect transistor (2) is greater than the width (WfinA) of the fin (15) of the first n-channel fin-type field effect transistor (1).

In the present invention, the width (WfinB) of the fin (25) of the n-channel fin-type field effect transistor (2) having a longer gate length (Lg) is set greater. When the width (WfinB) of the fin (25) is set greater, an upper surface region (23b) of the fin (25) can be set wider than a side surface region (23a) of the fin (25). As a result, the percentage of the upper surface region (23b) of the fin (25) included in the channel region can be increased. Here, the upper surface of the fin (25) formed on the first crystal plane ((100) by way of example) is the first crystal plane ((100) by way of example). Consequently, in the n-channel fin-type field effect transistor (2) having a longer gate length (Lg), the first crystal plane ((100) by way of example) having a carrier mobility higher than that of the second crystal plane ((110) by way of example) can act as the channel region.

When gate length (Lg) is longer, effects of short channel effect and random dopant fluctuation are smaller and current drive capacity has a higher importance. The width (WfinB) of the fin (25) is set greater, so that the region of the first crystal plane ((100) by way of example) having a carrier mobility higher than that of the second crystal plane ((110) by way of example) acts as the channel region of the n-channel fin-type field effect transistor (2); consequently, as illustrated in FIG. 8A, electron mobility can be improved. Thus, when gate length (Lg) is longer, current drive capacity can be improved while tolerance to short channel effect and reduction of random dopant fluctuation are not affected.

Meanwhile, for an n-channel fin-type field effect transistor (1) having a shorter gate length (Lg), the width (WfinA) of the fin (15) is set smaller. As a result, a fin-type field effect transistor is provided which has, similarly to a typical fin-type field effect transistor, advantages of tolerance to short channel effect and suppression of random dopant fluctuation. In this case, the width (WfinA) of the fin (15) is set smaller, so that the side surface region (13a) of the fin (15) is wider than the upper surface region (13b) of the fin (15). As a result, the percentage of the side surface region (13a) of the fin (15) included in the channel region is raised. Here, the side surface of the fin (15) may be the second crystal plane ((110) by way of example). However, as illustrated in FIG. 8, in the n-channel fin-type field effect transistor (1) having a shorter gate length (Lg), the current drive capacity of the second crystal plane ((110) by way of example) is substantially equal to that of the first crystal plane ((100) by way of example), and thus there is almost no need to consider characteristic deterioration.

According to the present invention, in a semiconductor device, transistor characteristics can be improved irrespective of gate length.

### BRIEF DESCRIPTION OF THE DRAWINGS

The above and other objects, advantages and features of the present invention will be more apparent from the following description taken in conjunction with the accompanying drawings, in which:

FIG. 1 is a plan view illustrating a structure of a semiconductor device disclosed in Patent Document 1;

FIG. 2 is a table showing a relationship between conduction type, fin width and gate length in a fin-type field effect transistor used as a semiconductor device according to an embodiment of the present invention;

FIG. 3 is a plan view illustrating a structure of the semiconductor device according to the embodiment of the present invention;

FIG. 4 is a cross-sectional view illustrating the structure of the semiconductor device according to the embodiment of the present invention;

FIG. 5 is a cross-sectional view illustrating another structure of the semiconductor device according to the embodiment of the present invention;

FIG. 6 is a plan view illustrating a structure of the semiconductor device according to the embodiment of the present invention;

FIG. 7 is a cross-sectional view illustrating the structure of the semiconductor device according to the embodiment of the present invention;

FIG. 8A is a graph showing a relationship between transistor drain current and gate length on Si (100) plane and Si (110) plane disclosed in Non-Patent Document 1;

FIG. 8B is a graph showing a relationship between transistor drain current and gate length on Si (100) plane and Si (110) plane disclosed in Non-Patent Document 1; and

FIG. 9 is a plan view illustrating a structure of a semiconductor device according to the embodiment of the present invention.

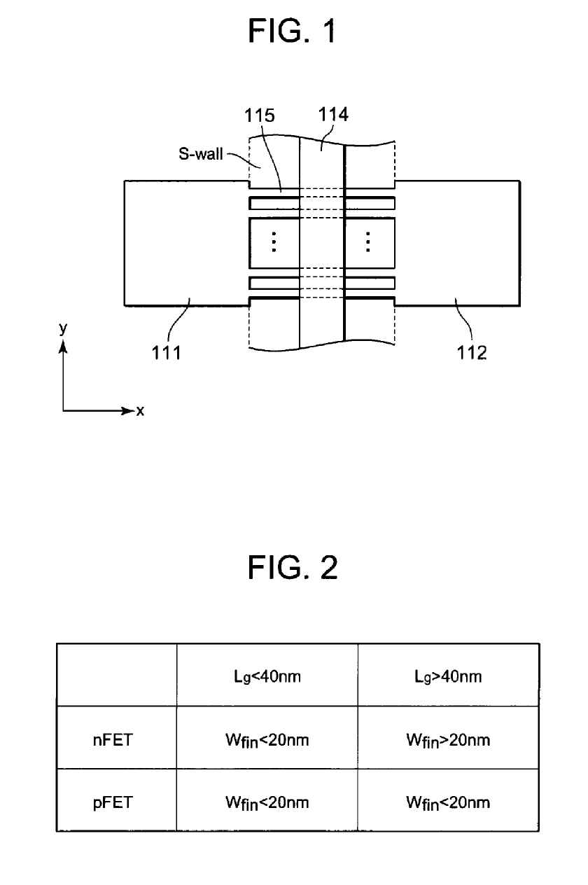

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

First, a structure of a semiconductor device according to an embodiment of the present invention will be described. FIG. 2 is a table showing a relationship between conduction type, fin width and gate length in a fin-type field effect transistor used as a semiconductor device according to an embodiment of the present invention. In this table, reference character nFET denotes an n-type fin-type field effect transistor; pFET, a p-type fin-type field effect transistor; Lg, gate length (nm); and Wfin, fin width (nm).

Consider that a fin-type field effect transistor is used as a transistor constituting an LSI. Fin-type field effect transistors include p-type FET (pFET) and n-type FET (nFET); and each of them includes a fin-type field effect transistor of a longer gate length and a fin-type field effect transistor of a shorter gate length. In this way, there are various gate lengths of the fin-type field effect transistor constituting an LSI. Typically, the fin width (Wfin) of the fin-type field effect transistor is preferably smaller. However, when consideration is given to current drive capacity, the fin-type field effect transistor of a smaller fin width is not always excellent from a viewpoint of current drive capacity when any of the gate lengths is used. This is because of the following two reasons.

The first reason is as follows: in a transistor of a longer gate length, short channel effect does not cause any problem, and random dopant fluctuation is also smaller, so that there is no advantage of using a fin-type field effect transistor of a smaller fin width. That is, it is thought that it must be determined based on the magnitude of gate length whether or not a fin-type field effect transistor of a smaller fin width is to be used. More specifically, when a gate length is used by which short channel effect and random dopant fluctuation cause a problem, the fin width of the fin-type field effect transistor may be lessened, and when a gate length is used by which the above problem does not occur, the fin width of the fin-type field effect transistor may be enlarged.

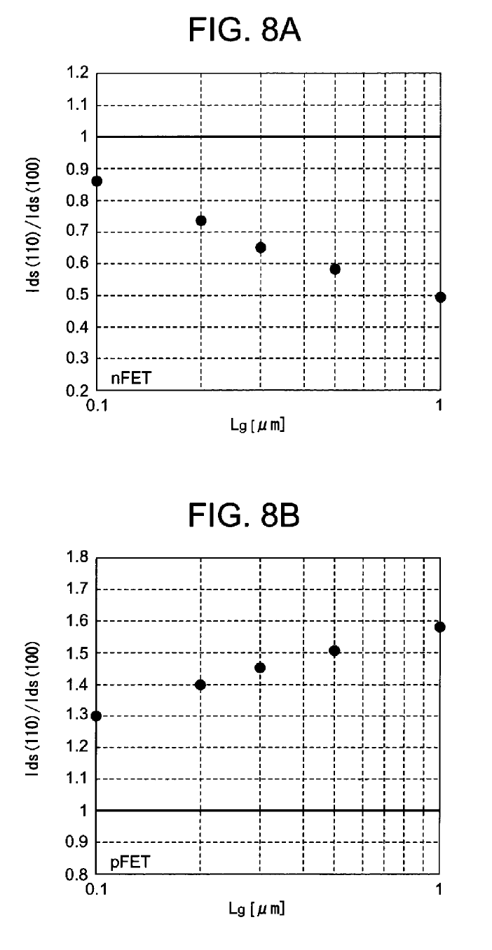

The second reason is as follows: as described with reference to FIGS. 8A and 8B, when a fin-type field effect transistor (nFET) is formed on a (100) plane substrate and a fin is formed in a <110> direction, the current drive capacity of the fin-type field effect transistor of a smaller fin width is approximately half of the current drive capacity of an ordinary MOSFET. That is, it is thought that it must be determined based on current drive capacity, conduction type and fin forming direction whether or not a fin-type field effect transistor of a smaller fin width is to be used. More specifically, in an n-type fin-type field effect transistor having a fin formed in a <110> direction, when current drive capacity is to be raised, the fin width of the fin-type field effect transistor may be enlarged, and otherwise the fin width of the fin-type field effect transistor may be lessened.

In this way, it is thought that when a fin-type field effect transistor is used as a transistor constituting an LSI, it must be determined based on gate length, current drive capacity, conduction type and fin forming direction whether or not a typical fin-type field effect transistor of a smaller fin width is to be used. In the present invention, conduction type (n-type, p-type), fin width (Wfin) and gate length (Lg) in the structure of the fin-type field effect transistor are set in the following way.

A fin-type field effect transistor according to the present embodiment has, as illustrated in FIG. 2, a structure for maximizing current drive capacity, irrespective of gate length. More specifically, the structure of the fin-type field effect transistor is characterized in that, when gate length Lg is smaller than a predetermined first value (40 nm by way of example) (smaller than 40 nm, by way of example), fin width Wfin is set smaller than a predetermined second value (20 nm by way of example) for both nFET and pFET (smaller than 20 nm, by way of example). When gate length is greater than the first value (greater than 40 nm, by way of example), fin width Wfin is set smaller than the second value for pFET (smaller than 20 nm, by way of example); and fin width Wfin is set greater than the second value for nFET (greater than 20 nm, by way of example). Here, there may be a difference of the first value and the second value between nFET and pFET. When gate length is equal to the first value, fin width Wfin may be set equal to, or greater than or smaller than the second value. A specific structure will be described below.

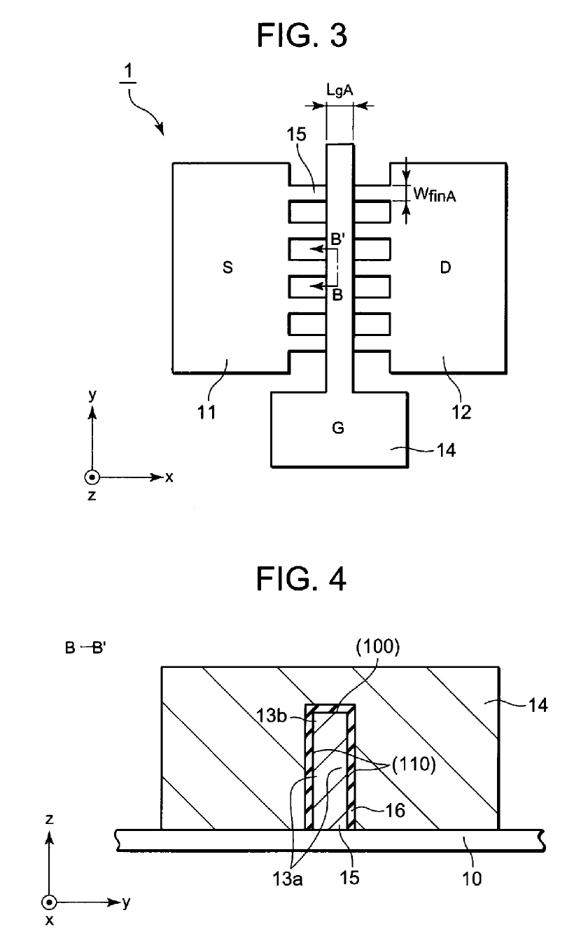

FIGS. 3 and 4 are a plan view and a cross-sectional view of the structure of the semiconductor device according to the embodiment of the present invention. FIG. 4 is a cross-sectional view along the line B-B′ of FIG. 3. FIGS. 3 and 4 illustrate the structure of a fin-type field effect transistor 1 having a smaller fin width.

In the fin-type field effect transistor 1, arranged on a semiconductor substrate 10 are a source 11, a drain 12, a gate 14 and multiple fins 15. The source 11 and the drain 12 are first-conduction type semiconductor layers. The source 11 and the drain 12 each have a substantially rectangular plate-like shape and are arranged side by side in the x-direction. The multiple fins 15 are second-conduction type semiconductor layers different from the first-conduction type. Each of the multiple fins 15 has a substantially rectangular fin-like shape and extends in the x-direction; and the multiple fins 15 are arranged in parallel with each other in the y-direction. Each of the multiple fins 15 has one end connected to the source 11 and the other end connected to the drain 12. The gate 14 is a first-conduction type semiconductor layer. The gate 14 extends in the y-direction and is arranged so as to cover the multiple fins 15. Arranged between the gate 14 and the multiple fins 15 is a gate insulating layer 16. That is, the gate 14 is connected via the gate insulating layer 16 to the fin 15. That part of the fin 15 connected via the gate insulating layer 16 to the gate 14 corresponds to a channel region 13 (13a, 13b). Gate length is an x-direction length of the channel region in the fin 15 (substantially the width of the gate 14). One of the first conduction type and the second conduction type is n-type; and the other is p-type.

Assuming that the surface of the semiconductor substrate 10 is (100) plane and the extending direction of the fin 15 in the x-y plane is <110> direction, the channel region 13a on the side surface of the fin 15 is (110) plane. In this case, the channel region 13b on the upper surface of the fin 15 is (100) plane. When the fin 15 has a smaller width, the channel region 13a of (110) plane occupies a greater percentage of the channel region 13. Consequently, referring to FIGS. 3 and 4, transistor characteristics reflecting those of (110) plane are provided. Here, when the fin 15 has a smaller width, the width of the fin 15 is preferably equal to or smaller than the height of the fin 15. In this case, the percentage of (110) plane in the channel region is approximately equal to or greater than 66%. More preferably, the width of the fin 15 is equal to or smaller than half of the height of the fin 15; in this case, this percentage is approximately equal to or greater than 80%. More preferably, the width of the fin 15 is even smaller than the height of the fin 15, so that the percentage of (110) plane in the channel region is approximately equal to or greater than 90%. The lower limit of the width of the fin 15 is, for example, 2 nm under manufacturing constraint.

In the case of nFET, when transistor characteristics of (110) plane are used, electron mobility lowers, as illustrated in FIG. 8A, and thus current drive capacity lowers. Consequently, in the structure illustrated in FIGS. 3 and 4, suppression of short channel effect and random dopant fluctuation has an importance higher than current drive capacity. However, as gate length becomes shorter (in the left side of FIG. 8A), transistor characteristics of (110) plane approaches those of (100) plane. This is because, in a region having a shorter gate length, contribution of carrier mobility to current drive capacity decreases due to velocity saturation effect. Therefore, when the above structure is used in a region having a shorter gate length, it is thought that transistor characteristics are substantially hardly affected. For example, in nFET, when gate length is shorter than 100 nm, current drive capacity of (110) plane is approximately 10% smaller than that of (100) plane. That is, in nFET having a shorter channel length, assuming that there is substantially no variation in current drive capacity and when suppression of short channel effect and random dopant fluctuation is considered, the above structure is preferably used.

On the other hand, in the case of pFET, when transistor characteristics of (110) plane are used, a higher hole mobility is, as illustrated in FIG. 8B, provided irrespective of channel length, so that a higher current drive capacity is provided. In this way, in the structure illustrated in FIGS. 3 and 4, effects of suppressing short channel effect and random dopant fluctuation are greater, and current drive capacity is also higher, which is preferable. That is, in pFET, when suppression of short channel effect and random dopant fluctuation is considered, the above structure is preferably used, irrespective of channel length.

Fin width WfinA is preferably 5 to 20 nm; and the height of the fin 15 is preferably 5 to 200 nm. The boundary fin width illustrated in FIG. 2 is 20 nm, by way of example. Gate length LgA is preferably 10 to 1000 nm. The boundary gate length illustrated in FIG. 2 is 40 nm, by way of example.

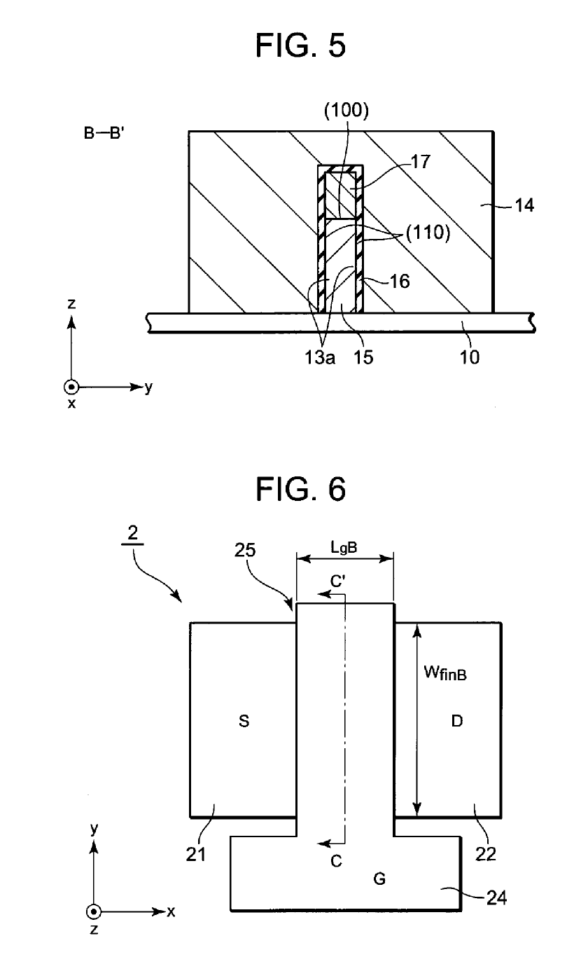

In the case of pFET, the channel region 13b of (100) plane is not so effective in transistor characteristics. Thus the upper surface of the fin 15 of (100) plane may not be used for the channel region. FIG. 5 is a cross-sectional view illustrating another structure of the semiconductor device according to the embodiment of the present invention; and FIG. 5 is a cross-sectional view along the line B-B′ of FIG. 3. According to this structure, another insulating layer 17 is arranged between the upper surface of the fin 15 of (100) plane and the gate insulating layer 16. The insulating layer 17 can make it difficult for a gate voltage from the gate 14 to be applied to the upper surface of the fin 15 of (100) plane. As a result, it is possible to prevent the upper surface of the fin 15 of (100) plane from acting as the channel region. Particularly, when gate length is longer, carrier mobility directly affects current drive capacity and thus such a structure is preferably used.

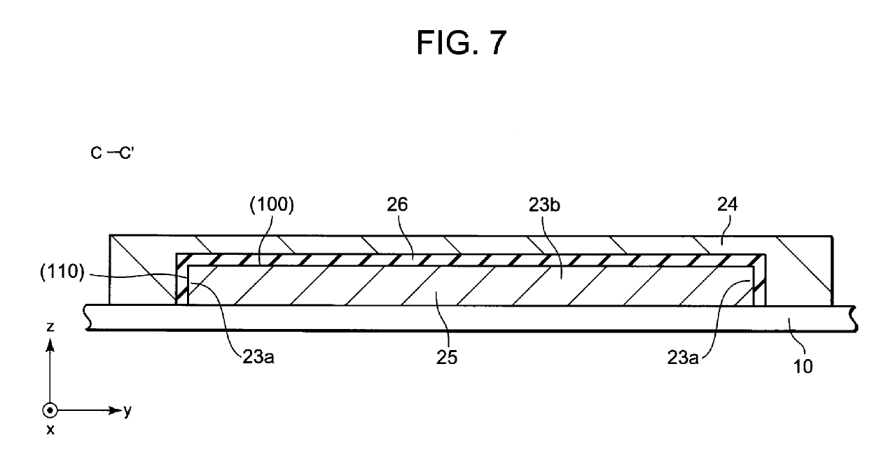

FIGS. 6 and 7 are a plan view and a cross-sectional view illustrating a structure of the semiconductor device according to the embodiment of the present invention; and FIG. 7 is a cross-sectional view along the line C-C′ of FIG. 6. FIGS. 6 and 7 illustrate a structure of a fin-type field effect transistor 2 having a greater fin width.

In the fin-type field effect transistor 2, arranged on a semiconductor substrate 20 are a source 21, a drain 22, a gate 24 and a fin 25. The source 21 and the drain 22 are first-conduction type semiconductor layers. The source 21 and the drain 22 each have a substantially rectangular plate-like shape and are arranged side by side in the x-direction. The fin 25 is a second-conduction type semiconductor layer different from the first-conduction type. The fin 25 has a substantially rectangular fin-like shape. The fin 25 has one end connected to the source 21 and the other end connected to the drain 22. The gate 24 is a first-conduction type semiconductor layer. The gate 14 extends in the y-direction and is arranged so as to cover the fin 25. Arranged between the gate 24 and the fin 25 is a gate insulating layer 26. That is, the gate 24 is connected via the gate insulating layer 26 to the fin 25. That part of the fin 25 connected via the gate insulating layer 26 to the gate 24 corresponds to a channel region 23 (23a, 23b). Gate length is an x-direction length of the channel region in the fin 25 (substantially the width of the gate 24). One of the first conduction type and the second conduction type is n-type; and the other is p-type.

Assuming that the surface of the semiconductor substrate 20 is (100) plane and the extending direction of the fin 25 in the x-y plane is <110> direction, the channel region 23a on the side surface of the fin 25 is (110) plane. In this case, the channel region 23b on the upper surface of the fin 25 is (100) plane. When the fin 25 has a greater width, the channel region 23a of (100) plane occupies a greater percentage of the channel region 23. Consequently, referring to FIGS. 6 and 7, transistor characteristics reflecting those of (100) plane are provided. On the other hand, a major part of the channel region constitutes a uniform flat surface, and therefore it is thought that the channel region is, similarly to an ordinary MOSFET, readily affected by short channel effect. Here, when the fin 25 has a greater width, the width of the fin 25 is preferably equal to or greater than at least quadruple the height of the fin 25. In this case, the percentage of (100) plane in the channel region is equal to or greater than approximately 66%. More preferably, the width of the fin 25 is equal to or greater than octuple the height of the fin 25; in this case, the percentage is equal to or greater than appropriately 80%. More preferably, the width of the fin 25 is even greater than the height of the fin 25, so that the percentage of (100) plane in the channel region is equal to or greater than appropriately 90%. The upper limit of the width of the fin 25 is, for example, 1000 nm under design constraint.

In the case of nFET, when transistor characteristics of (100) plane are used, electron mobility is, as illustrated in FIG. 8A, higher and thus current drive capacity rises. Since such a structure is preferably used when gate length is greater and there is no need to consider suppression of short channel effect and random dopant fluctuation, current drive capacity has a higher importance. That is, this structure is preferably used in nFET having a longer channel length.

However, in the case of pFET, when transistor characteristics of (100) plane are used, electron mobility lowers, as illustrated in FIG. 8A, and thus current drive capacity lowers. Such a structure is readily affected by short channel effect and random dopant fluctuation and also has a lower current drive capacity, which is improper for pFET. That is, this structure is preferably not used in pFET, irrespective of channel length.

Fin width WfinB is preferably 20 to 1000 nm; and the height of the fin 25 is preferably 5 to 200 nm. The boundary fin width illustrated in FIG. 2 is, as described above, 20 nm, by way of example. Gate length LgB is preferably 40 to 1000 nm. The boundary gate length illustrated in FIG. 2 is, as described above, 40 nm, by way of example. Preferably, there is no difference of the height of the fin 25 between the fin-type field effect transistor 1 and the fin-type field effect transistor 2 so that manufacturing is facilitated.

To summarize the above, a fin-type field effect transistor according to the embodiment of the present invention has the structure shown in FIG. 2.

(1) nFET

First, when gate length is longer, short channel effect or random dopant fluctuation hardly occurs. Thus, a fin-type field effect transistor having a smaller fin width does not always have to be manufactured, but it is sufficient to maximize current drive capacity. In the case of nFET, when such a structure is used, (100) plane is, as evident from FIG. 8A, preferably used as the channel region. Consequently, the structure illustrated in FIGS. 6 and 7 is preferably used.

On the other hand, when gate length is shorter, short channel effect or random dopant fluctuation may occur. Accordingly, a fin-type field effect transistor having a smaller fin width must be manufactured. In this case, (110) plane is used as the channel region, as illustrated in FIGS. 3 and 4. In this case, it is thought from FIG. 8A that, when gate length is shorter, there is no significant difference of characteristics between (100) plane and (110) plane; thus there is no problem.

Accordingly, in the case of nFET, when gate length is longer, the structure illustrated in FIGS. 6 and 7 is used; and when gate length is shorter, the structure illustrated in FIGS. 3 and 4 is used. In the example of FIG. 2, a gate length Lg of 40 nm and a fin width Wfin of 20 nm are used as a reference value, and when gate length is greater than the reference value (Lg>40 nm), a structure having a greater fin width (Wfin>20 nm) (FIGS. 6 and 7) is used; but when gate length is shorter than the reference value (Lg<40 nm), a structure having a shorter fin width (Wfin<20 nm) (FIGS. 3 and 4) is used. In this case, fin width Wfin may vary according to gate length Lg under the above condition.

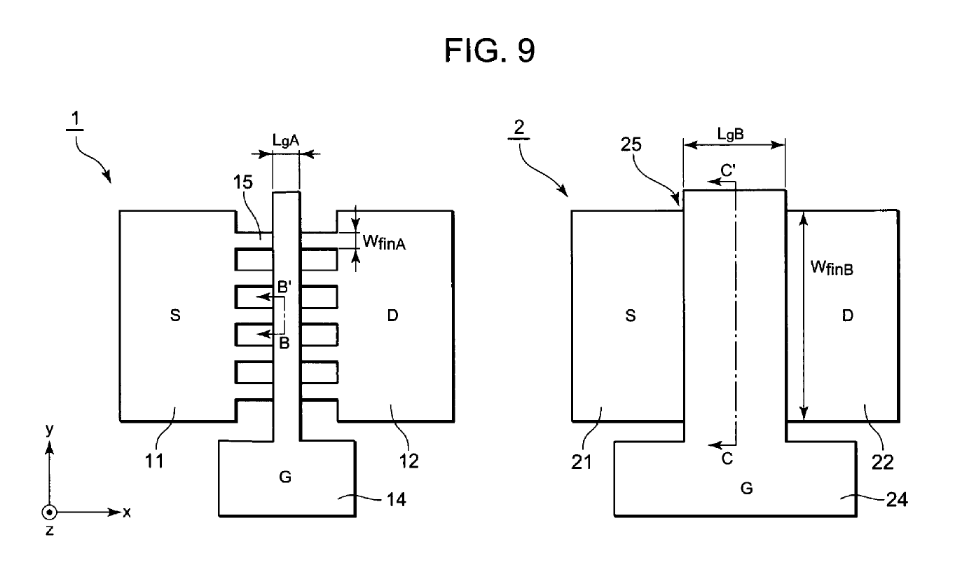

FIG. 9 is a plan view illustrating a structure of a semiconductor device according to the embodiment of the present invention. The semiconductor device includes, on a first crystal plane (not illustrated);
a first n-channel fin-type field effect transistor 1 having a gate length of LgA; and
a second n-channel fin-type field effect transistor 2 having a gate length of LgB greater than the gate length of LgA,
wherein a side surface of a fin 15 of the first re-channel fin-type field effect transistor 1 and a side surface of a fin 25 of the second n-channel fin-type field effect transistor 2 are both formed on a second crystal plane having a carrier mobility lower than that of the first crystal plane, and
wherein width WfinB of the fin 25 of the second n-channel fin-type field effect transistor 2 is formed greater than that of the fin 15 of the first n-channel fin-type field effect transistor.
   (2) pFET

When gate length is longer, short channel effect or random dopant fluctuation hardly occurs. Thus, a fin-type field effect transistor having a smaller fin width does not always have to be manufactured, but it is sufficient to maximize current drive capacity. In the case of pFET, when such a structure is used, (110) plane is, as evident from FIG. 8B, preferably used as the channel region. Consequently, the structure illustrated in FIGS. 3 and 4 is preferably used.

On the other hand, when gate length is shorter, short channel effect or random dopant fluctuation may occur. Accordingly, a fin-type field effect transistor having a smaller fin width must be manufactured. In this case, a structure is used which has, as illustrated in FIGS. 3 and 4, a shorter gate length and uses (110) plane as the channel region. When gate length is shorter, as evident from FIG. 8B, characteristics of (110) plane is more excellent than those of (100) plane. From the above reasons, the structure illustrated in FIGS. 3 and 4 is preferably used.

Accordingly, in the case of pFET, the structure illustrated in FIGS. 3 and 4 is used, irrespective of gate length. Referring to FIG. 2, a gate length Lg of 40 nm and a fin width Wfin of 20 nm are used as a reference value, and independently of whether gate length is longer than the reference value (Lg>40 nm) or shorter than the reference value (Lg<40 nm), a structure having a smaller fin width (Wfin<20 nm) (FIGS. 3 and 4) is used. In this case, fin width Wfin may vary according to gate length Lg under the above condition.

When the above described structure is used, the current drive capacity of the semiconductor device (fin-type field effect transistor) according to the present invention can be maximized, irrespective of gate length.

In this way, according to the present invention, when a transistor nFET or pFET having a shorter gate length is constructed using a fin-type field effect transistor having a shorter fin width, a high performance transistor is implemented which has a higher tolerance to short channel effect and a smaller random dopant fluctuation. Further, in a transistor nFET or pFET having a longer gate length, fin width does not need be shortened from a viewpoint of short channel effect and random dopant fluctuation. However, from a viewpoint of current drive capacity, a fin-type field effect transistor having a greater fin width is used as nFET, so that the percentage of (100) region is raised. Accordingly, the ratio of the channel width of (100) region to the channel width of (110) region is raised to improve the average electron mobility, thus improving current drive capacity. As a result, current drive capacity is improved approximately twice as high as a fin-type field effect transistor having a smaller fin width. On the other hand, a fin-type field effect transistor having a smaller fin width is used as pFET, so that the percentage of (110) region is raised. Accordingly, the ratio of the channel width of (110) region to the channel width of (100) region is raised to improve the average hole mobility, thus improving current drive capacity. As a result, current drive capacity is improved approximately 1.5 times as high as a fin-type field effect transistor having a greater fin width.

In the above described embodiment, descriptions have been given based on the relationship of carrier mobility between (100) plane and (110) plane illustrated in FIGS. 8A and 8B. However, the present invention is not limited to (100) plane and (110) plane, and may be applied to any two crystal planes (first crystal plane and second crystal plane) having a relationship of carrier mobility therebetween as illustrated in FIGS. 8A and 8B.

It is apparent that the present invention is not limited to the above embodiments, but may be modified and changed without departing from the scope and spirit of the invention.

What is claimed is:

1. A semiconductor device comprising:
a first n-channel fin-type field effect transistor formed on a first crystal plane; and
a second n-channel fin-type field effect transistor formed on the first crystal plane and having a gate length longer than that of the first n-channel fin-type field effect transistor,
wherein a side surface of a fin of the first n-channel fin-type field effect transistor and a side surface of a fin of the second n-channel fin-type field effect transistor are both formed on a second crystal plane having a carrier mobility lower than that of the first crystal plane, and
wherein the width of the fin of the second n-channel fin-type field effect transistor is greater than the width of the fin of the first n-channel fin-type field effect transistor.

2. The semiconductor device according to claim 1,
wherein the first crystal plane is (100) plane.

3. The semiconductor device according to claim 2,
wherein the second crystal plane is (110) plane.

4. The semiconductor device according to claim 3, further comprising a first p-channel fin-type field effect transistor formed on the (100) plane,
wherein the width of a fin of the first p-channel fin-type field effect transistor is smaller than the width of the fin of the second n-channel fin-type field effect transistor.

5. The semiconductor device according to claim 4, further comprising a second p-channel fin-type field effect transistor formed on the (100) plane and having a gate length longer than that of the first p-channel fin-type field effect transistor,
wherein the width of a fin of the second p-channel fin-type field effect transistor is smaller than the width of the fin of the second n-channel fin-type field effect transistor.

6. The semiconductor device according to claim 5,
wherein a side surface of the fin of the second p-channel fin-type field effect transistor and a side surface of the fin of the first p-channel fin-type field effect transistor are (110) plane.

7. The semiconductor device according to claim 6,
wherein the film thickness of an insulating layer in contact with an upper side surface of the fin of the second p-channel fin-type field effect transistor is greater than the film thickness of the insulating layer in contact with a side surface thereof.

8. The semiconductor device according to claim 5,
wherein the width of the fin of the first p-channel fin-type field effect transistor and the width of the fin of the second n-channel fin-type field effect transistor are equal to or smaller than the height of the respective fins.
